(19) United States
(12) Patent Application Publication
(10) Pub. No.: US 2024/0128325 A1
(43) Pub. Date: Apr. 18, 2024

(54) SEMICONDUCTOR STRUCTURE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hajime NAGO, Yokohama (JP); Hisashi YOSHIDA, Kawasaki (JP); Jumpei TAJIMA, Mitaka (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/354,809

(22) Filed: Jul. 19, 2023

(30) Foreign Application Priority Data
Oct. 14, 2022 (JP) 2022-165601

(51) Int. Cl. H01L 29/20; H01L 29/04; H01L 29/15

(52) U.S. Cl. CPC H01L 29/2003; H01L 29/045; H01L 29/155; H01L 29/7786

(57) ABSTRACT

According to one embodiment, a semiconductor structure includes a substrate including silicon crystal, a first layer including AlN crystal, and an intermediate region provided between the silicon crystal and the AlN crystal. The intermediate region includes Al and nitrogen. A direction from the silicon crystal to the AlN crystal is along a first direction. A third lattice plane spacing in the first direction of a lattice of Al atoms in the intermediate region is longer than a first lattice plane spacing in the first direction of the silicon crystal and longer than a second lattice plane spacing in the first direction of the AlN crystal.

### CROSS-REFERENCE TO RELATED APPLICATIONS

This application is based upon and claims the benefit of priority from Japanese Patent Application No. 2022-165601, filed on Oct. 14, 2022; the entire contents of which are incorporated herein by reference.

### FIELD

Embodiments of the invention generally relate to a semiconductor structure and a semiconductor device.

### BACKGROUND

For example, improved characteristics are desired in semiconductor devices based on semiconductor structures.

### BRIEF DESCRIPTION OF THE DRAWINGS

FIG. 1 is a schematic cross-sectional view illustrating a semiconductor structure according to a first embodiment;

FIG. 2 is a schematic diagram illustrating the semiconductor structure according to the first embodiment;

FIG. 3 is a graph illustrating characteristics of the semiconductor structure;

FIGS. 4A and 4B are electron microscope images of the semiconductor structure;

FIGS. 5A and 5B are graphs illustrating characteristics of semiconductor structures;

FIG. 6 is a graph illustrating characteristics of the semiconductor structure;

FIG. 7 is a schematic cross-sectional view illustrating the semiconductor structure according to the first embodiment;

FIG. 8 is a schematic cross-sectional view illustrating a semiconductor device according to a second embodiment; and

FIG. 9 is a schematic cross-sectional view illustrating the semiconductor device according to the second embodiment.

### DETAILED DESCRIPTION

According to one embodiment, a semiconductor structure includes a substrate including silicon crystal, a first layer including AlN crystal, and an intermediate region provided between the silicon crystal and the AlN crystal. The intermediate region includes Al and nitrogen. A direction from the silicon crystal to the AlN crystal is along a first direction. A third lattice plane spacing in the first direction of a lattice of Al atoms in the intermediate region is longer than a first lattice plane spacing in the first direction of the silicon crystal and longer than a second lattice plane spacing in the first direction of the AlN crystal.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

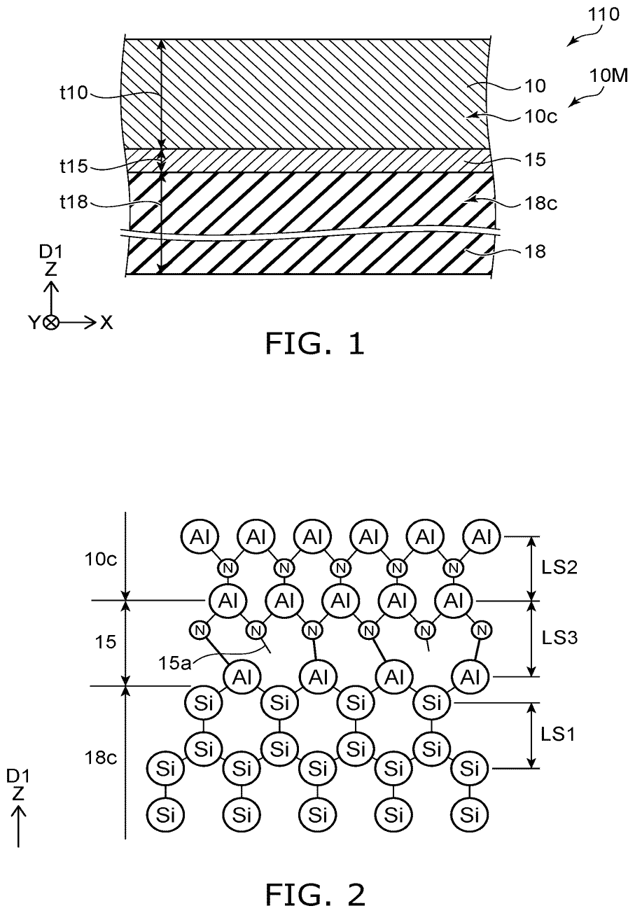

FIG. 1 is a schematic cross-sectional view illustrating a semiconductor structure according to the first embodiment.

As shown in FIG. 1, a semiconductor structure 110 according to the embodiment includes a substrate 18, a first layer 10 and an intermediate region 15.

The substrate 18 includes a silicon crystal 18c. The first layer 10 includes AlN crystal 10c. The intermediate region 15 is provided between the silicon crystal 18c and the AlN crystal 10c. The intermediate region 15 includes Al and nitrogen. The intermediate region 15 is a transition region.

A direction from the silicon crystal 18c to the AlN crystal 10c is defined as a first direction D1. The first direction D1 corresponds to a direction from the substrate 18 to the first layer 10. The first direction D1 is defined as a Z-axis direction. One direction perpendicular to the Z-axis direction is defined as an X-axis direction. A direction perpendicular to the Z-axis direction and the X-axis direction is defined as a Y-axis direction. The substrate 18 and first layer 10 extend parallel to the X-Y plane.

The AlN crystal 10c is a hexagonal crystal. For example, the c-plane of the AlN crystal 10c crosses the first direction D1. For example, the c-axis of the AlN crystal 10c is along the first direction D1. In the embodiments, the c-axis may be tilted with respect to the first direction D1. The angle between the c-axis and the first direction D1 is 10 degrees or less.

FIG. 2 is a schematic diagram illustrating the semiconductor structure according to the first embodiment.

FIG. 2 illustrates the crystal states of the silicon crystal 18c, the intermediate region 15, and the AlN crystal 10c.

As shown in FIG. 2, the silicon crystal 18c has a first lattice plane spacing LS1 in the first direction D1. The AlN crystal 10c has a second lattice plane spacing LS2 in the first direction D1. Al atoms are arranged in a lattice in the intermediate region 15. The lattice plane spacing in the first direction D1 of the lattice of Al atoms in the intermediate region 15 is defined as a third lattice plane spacing LS3.

In the embodiment, the third lattice plane spacing LS3 in the first direction D1 of the lattice of Al atoms in the intermediate region 15 is longer than the first lattice plane spacing LS1 and longer than the second lattice plane spacing LS2.

By providing such an intermediate region 15, an AlN crystal 10c of high crystal quality can be obtained. For example, a low dislocation density is obtained in the first layer 10. For example, high breakdown voltage can be obtained.

Examples of experimental results independently carried out by the inventors of the present application will be described below.

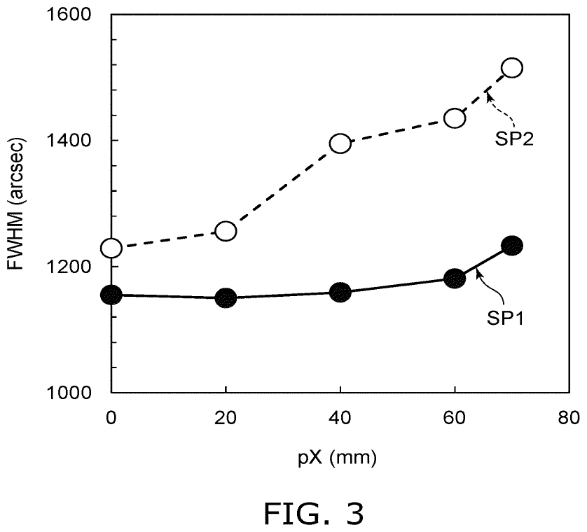

FIG. 3 is a graph illustrating characteristics of the semiconductor structure.

FIG. 3 illustrates evaluation results of a first sample SP1 and a second sample SP2. These samples are obtained by epitaxially growing the AlN crystal 10c on the silicon crystal 18c. In the epitaxial growth, a second processing is performed after a first processing of supplying a first gas including Al to the surface of the silicon crystal 18c. In the second processing, the first gas and the second gas including nitrogen are supplied to form the AlN crystal 10c. In this example, a flow rate of the first gas is 84 μmol in the first processing.

The first processing time for the first sample SP1 is shorter than the first processing time for the second sample SP2. Except for this, the processing conditions are the same for the first sample SP1 and the second sample SP2. The first gas is TMA (trimethylaluminum). The second gas is ammonia. For these samples, the crystal quality of the AlN crystal 10c is evaluated by X-ray diffraction.

The horizontal axis of FIG. 3 is the position in the X-axis direction of the samples. The vertical axis is the full width at half maximum (FWHM) for the (002) plane of the X-ray diffraction image of the AlN crystal 10c. A small FWHM corresponds to small fluctuations and high crystal quality in the AlN crystal 10c.

As shown in FIG. 3, the FWHM of the first sample SP1 is smaller than the FWHM of the second sample SP2. The FWHM of the first sample SP1 is 1200 arcsec or less.

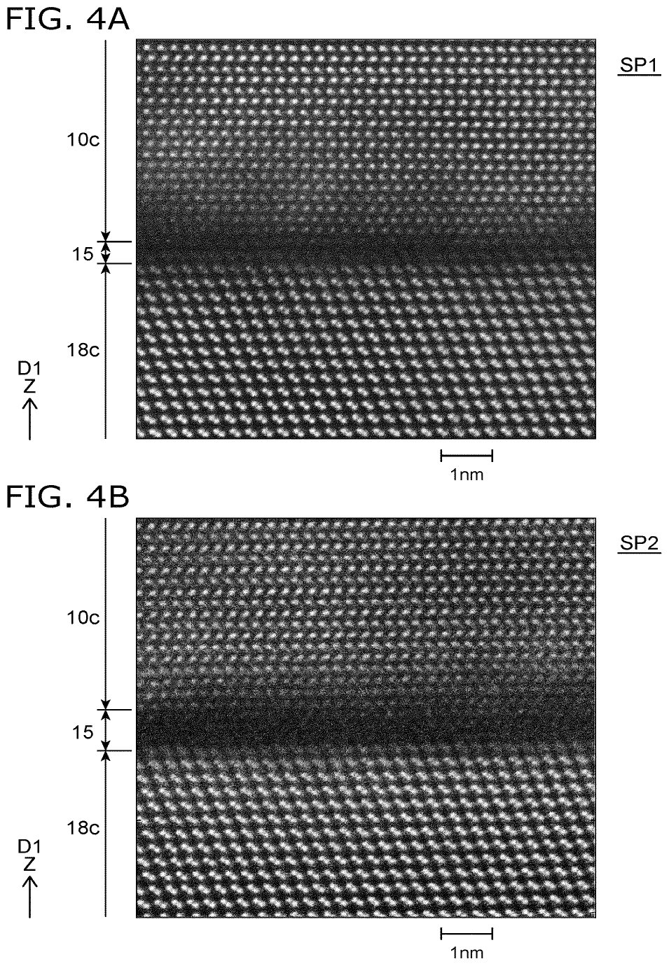

FIGS. 4A and 4B are electron microscope images of the semiconductor structure.

FIG. 4A corresponds to the first sample SP1. FIG. 4B corresponds to the second sample SP2. These figures are HAADF-STEM (high-angle annular dark-field scanning transmission electron microscopy) images.

As shown in FIG. 4B, in the second sample SP2, disorder exist in the arrangement of atoms in the intermediate region 15. As shown in FIG. 4A, atoms are regularly arranged in the intermediate region 15 in the first sample SP1.

For example, it is possible to derive a lattice plane spacing from HAADF-STEM images.

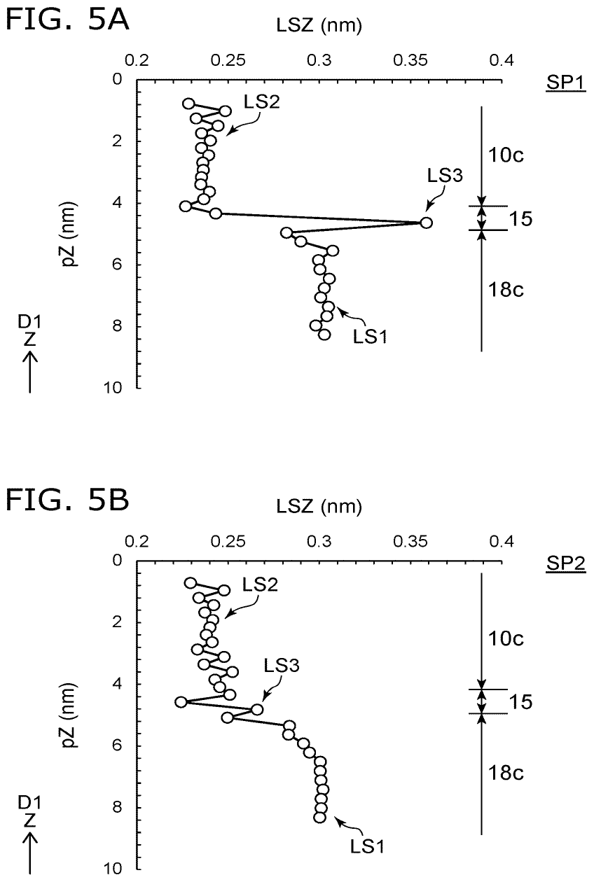

FIGS. 5A and 5B are graphs illustrating characteristics of semiconductor structures.

FIG. 5A corresponds to the first sample SP1. FIG. 5B corresponds to the second sample SP2. The vertical axis of these figures is the position pZ in the Z-axis direction. The horizontal axis is the lattice plane spacing LSZ in the Z-axis direction. These figures show a first lattice plane spacing LS1 in the silicon crystal 18c, a third lattice plane spacing LS3 in the intermediate region 15, and a second lattice plane spacing LS2 in the AlN crystal 10c.

As shown in FIGS. 5A and 5B, the first lattice plane spacing LS1 is longer than the second lattice plane spacing LS2 in the first sample SP1 and the second sample SP2. The first lattice plane spacing LS1 is considered to be a lattice plane spacing inherent to the silicon crystal 18c. The second lattice plane spacing LS2 is considered to be a lattice plane spacing inherent to the AlN crystal 10c.

As shown in FIG. 5B, in the second sample SP2, the third lattice plane spacing LS3 is between the first lattice plane spacing LS1 and the second lattice plane spacing LS2, and the lattice plane spacing LSZ changes monotonously.

On the other hand, as shown in FIG. 5A, in the first sample SP1, the third lattice plane spacing LS3 is longer than the first lattice plane spacing LS1 and longer than the second lattice plane spacing LS2. In the intermediate region 15, the lattice plane spacing LSZ is locally long.

In the first sample SP1 in which the AlN crystal 10c with good crystallinity is obtained, specific characteristics illustrated in FIG. 5A are obtained.

In the first sample SP1, it is considered that, for example, crystal strain is relaxed due to the lattice plane spacing being locally lengthened in the intermediate region 15. As a result, Al atoms tend to be regularly arranged in the intermediate region 15. Thereby, a small FWHM is obtained in the AlN crystal 10c. For example, high crystal quality is obtained. According to the embodiments, it is possible to provide a semiconductor structure capable of improving characteristics. For example, a semiconductor structure with few crystal defects can be provided. For example, it is possible to provide a semiconductor structure capable of improving vertical breakdown voltage characteristics.

In the embodiment, the second lattice plane spacing LS2 is shorter than the first lattice plane spacing LS1. The third lattice plane spacing LS3 is 1.1 times or more the first lattice plane spacing LS1.

For example, the first lattice plane spacing LS1 is not less than 0.28 nm and less than 0.32 nm. The second lattice plane spacing LS2 is not less than 0.22 nm and not more than 0.26 nm. The third lattice plane spacing LS3 is not less than 0.32 nm and not more than 0.38 nm.

For example, the first lattice plane spacing LS1 is approximately 0.3 nm. The second lattice plane spacing LS2 is approximately 0.24 nm. The third lattice plane spacing LS3 is approximately 0.35 nm.

The third lattice plane spacing LS3 in the intermediate region 15 can be controlled by, for example, conditions of the first processing when forming the AlN crystal 10c on the silicon crystal 18c. For example, it has been found that the third lattice plane spacing LS3 can be controlled by the duration of the first processing. Furthermore, it has been found that the third lattice plane spacing LS3 can be controlled by the flow rate of the first gas in the first processing.

When transitioning from the first lattice plane spacing LS1 to the second lattice plane spacing LS2, it is natural that the lattice plane spacing LSZ changes monotonically and continuously, and it is natural to assume that good crystallinity is easily obtained at this situation. However, as shown in FIG. 5A, when the transition from the first lattice plane spacing LS1 to the second lattice plane spacing LS2 is made, it has been found that good crystallinity can be obtained by the existence of the third lattice plane spacing LS3 that is longer than the first lattice plane spacing LS1 and longer than the second lattice plane spacing LS2. This is a newly discovered knowledge by the inventors of the present application.

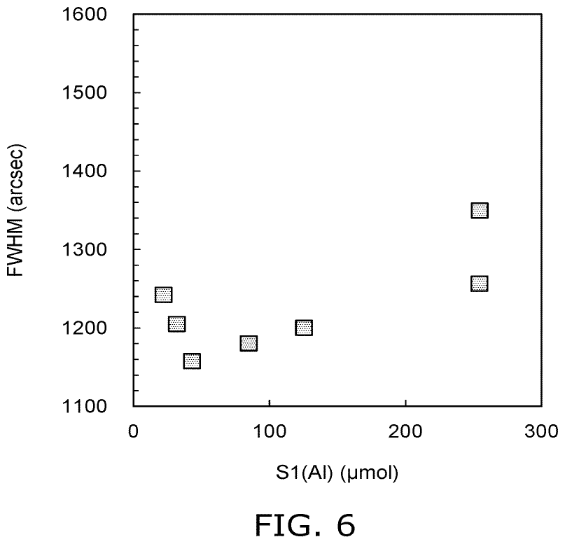

FIG. 6 is a graph illustrating characteristics of the semiconductor structure.

The horizontal axis of FIG. 6 is the flow rate S1(Al) of the first gas (TMA) including Al in the first processing. The vertical axis is the full width at half maximum (FWHM) for the (002) plane of the X-ray diffraction image of the AlN crystal 10c.

As shown in FIG. 6, when the flow rate S1(Al) is in the range of 40 μmol or less, the FWHM decreases as the flow rate S1(Al) increases. In the range where the flow rate S1(Al) is 40 μmol or more, the FWHM increases as the flow rate S1(Al) increases. The flow rate S1 (Al) is preferably not less than 30 μmol and not more than 80 μmol. Small FWHM is easy to obtain.

In the embodiment, a thickness t15 (see FIG. 1) of the intermediate region 15 along the first direction D1 is preferably, for example, not less than 0.32 nm and not more than 1.0 nm. For example, small FWHM is easy to be obtained.

A thickness t10 (see FIG. 1) of the first layer 10 along the first direction D1 is preferably not less than 150 nm and not more than 300 nm. For example, it is easy to obtain high flatness.

A thickness t18 (see FIG. 1) of the substrate 18 along the first direction D1 is preferably not less than 625 μm and not more than 1035 μm. In the embodiment, the plane of the silicon crystal 18c facing the intermediate region 15 is, for example, the (111) plane.

As shown in FIG. 2, nitrogen atoms included in intermediate region 15 may include dangling bonds 15a.

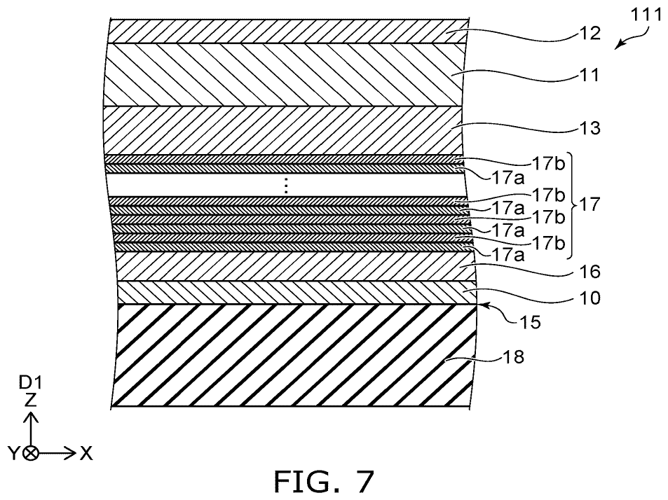

FIG. 7 is a schematic cross-sectional view illustrating the semiconductor structure according to the first embodiment.

As shown in FIG. 7, a semiconductor structure 111 according to the embodiment may further include an AlGaN layer 16. Except for this, the configuration of the semiconductor structure 111 may be the same as the configuration of the semiconductor structure 110.

A first layer 10 is provided between the substrate 18 and the AlGaN layer 16. The AlGaN layer 16 is at least a part of the buffer layer.

As shown in FIG. 7, the semiconductor structure 111 may further include multi-layer structure 17. The AlGaN layer 16 is provided between the substrate 18 and the multilayer structure 17. The multilayer structure 17 includes a plurality of first films 17a and a plurality of second films 17b. The plurality of first films 17a and the plurality of second films 17b include a nitride semiconductor. The nitride semiconductor includes, for example, BₓIn_{y}Al_{z}Ga_{1-xyz}N (0≤x≤1, 0≤y≤1, 0≤z≤1, x+y+z≤1). In one example, the plurality of first films 17a includes GaN. The plurality of second films 17b include AlGaN or AlN. One of the plurality of first films 17a is located between one of the plurality of second films 17b and another one of the plurality of second films 17b. One of the plurality of second films 17b is located between one of the plurality of first films 17a and another one of the plurality of first films 17a. The multilayer structure 17 is at least a part of the buffer layer.

As shown in FIG. 7, the semiconductor structure 111 may further include a first semiconductor layer 11 and a second semiconductor layer 12. The first semiconductor layer 11 includes Alₓ₁Ga₁₋ₓ₁N (0≤x1<1). The composition ratio x1 is not less than 0 and not more than 0.1. The first semiconductor layer 11 includes GaN, for example. The second semiconductor layer 12 includes Alₓ₂Ga₁₋ₓ₂N (0<x2≤1, x1<x2). The composition ratio x2 is, for example, not less than 0.2 and not more than 0.45. The second semiconductor layer 12 includes AlGaN. The first layer 10 is provided between the substrate 18 and the second semiconductor layer 12. The first semiconductor layer 11 is provided between the first layer 10 and the second semiconductor layer 12.

As shown in FIG. 7, the semiconductor structure 111 may further include a third semiconductor layer 13. The third semiconductor layer 13 includes Alₓ₃Ga₁₋ₓ₃N (0≤x3<1, x3<x2) including carbon. The composition ratio x3 is, for example, not less than 0 and not more than 0.1. The third semiconductor layer 13 includes, for example, GaN including carbon. The third semiconductor layer 13 is provided between the first layer 10 and the first semiconductor layer 11.

In the semiconductor structure 111, the third lattice plane spacing LS3 is longer than the first lattice plane spacing LS1 and longer than the second lattice plane spacing LS2. As a result, edge dislocation density can be reduced in layers above the first layer 10 (for example, the multilayer structure 17 and/or the first semiconductor layer 11).

For example, the edge dislocation density in the semiconductor structure 111 based on the first sample SP1 is about 1×10¹⁰ cm⁻². On the other hand, the edge dislocation density in the semiconductor structure based on the second sample SP2 is about 3.8×10¹⁰ cm⁻².

For example, a high breakdown voltage can be obtained in the semiconductor structure 111 based on the first sample SP1. In the semiconductor structure 111 based on the first sample SP1, pass rate of the breakdown voltage test is 100%. On the other hand, pass rate of the semiconductor structure based on the second sample SP2 in the breakdown voltage test is 92%.

### Second Embodiment

The second embodiment relates to a semiconductor device.

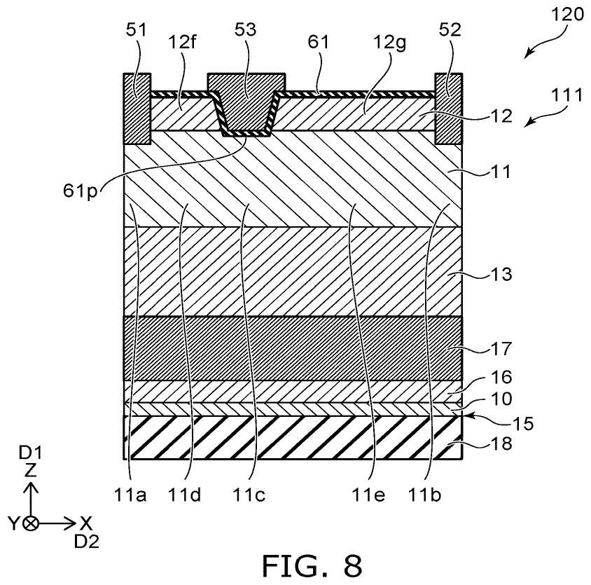

FIG. 8 is a schematic cross-sectional view illustrating a semiconductor device according to the second embodiment.

As shown in FIG. 8, a semiconductor device 120 according to the embodiment includes a semiconductor structure (for example, the semiconductor structure 111) according to the first embodiment, a first electrode 51, a second electrode 52, and a third electrode 53.

A second direction D2 from the first electrode 51 to the second electrode 52 crosses the first direction D1. The second direction D2 is, for example, the X-axis direction. A position of the third electrode 53 in the second direction D2 is between a position of the first electrode 51 in the second direction D2 and a position of the second electrode 52 in the second direction D2.

The first semiconductor layer 11 includes a first partial region 11a, a second partial region 11b and a third partial region 11c. A direction from the first partial region 11a to the first electrode 51 is along the first direction D1. A direction from the second partial region 11b to the second electrode 52 is along the first direction D1. The third partial region 11c is between the first partial region 11a and the second partial region 11b in the second direction D2. A direction from the third partial region 11c to the third electrode 53 is along the first direction D1.

The first electrode 51 is electrically connected to the first partial region 11a. The second electrode 52 is electrically connected to second partial region 11b.

A current flowing between the first electrode 51 and the second electrode 52 can be controlled by a potential of the third electrode 53. The potential of the third electrode 53 may be a potential based on a potential of the first electrode 51. The first electrode 51 functions, for example, as a source electrode. The second electrode 52 functions, for example, as a drain electrode. The third electrode 53 functions, for example, as a gate electrode. The semiconductor device 120 is, for example, a transistor.

The first semiconductor layer 11 includes a region facing the second semiconductor layer 12. A carrier region is formed in this region. The carrier region is, for example, a two-dimensional electron gas. The semiconductor device 120 is, for example, a HEMT (High Electron Mobility Transistor).

In the embodiment, by providing the intermediate region 15 described above, for example, high carrier mobility can be obtained. For example, a low on-resistance can be obtained.

As shown in FIG. 8, the first semiconductor layer 11 may further include a fourth partial region 11d and a fifth partial region 11e. The fourth partial region 11d is located between the first partial region 11a and the third partial region 11c in the second direction D2. The fifth partial region 11e is located between the third partial region 11c and the second partial region 11b in the second direction D2.

The second semiconductor layer 12 includes a sixth partial region 12f and a seventh partial region 12g. A direction from the fourth partial region 11d to the sixth partial region 12f is along the first direction D1. A direction from the fifth partial region 11e to the seventh partial region 12g is along the first direction D1.

As shown in FIG. 8, the semiconductor device 120 may further include an insulating member 61. At least a part (part 61p) of the insulating member 61 is located between the third partial region 11c and the third electrode 53.

As shown in FIG. 8, at least a part of the third electrode 53 may be located between the sixth partial region 12f and the seventh partial region 12g in the second direction D2. For example, it is easy to obtain normally-off operation.

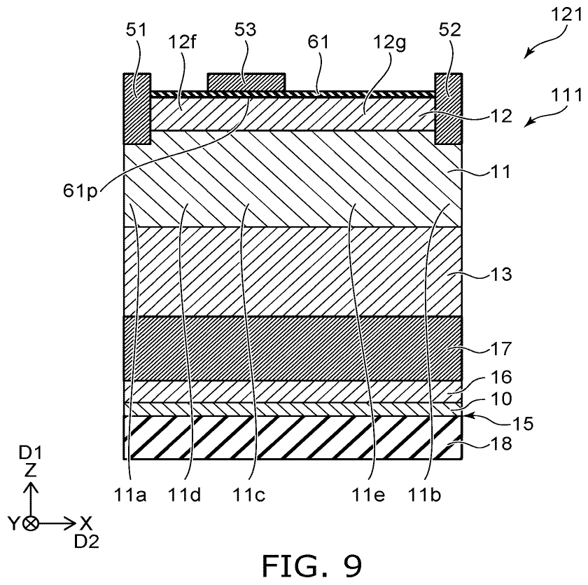

FIG. 9 is a schematic cross-sectional view illustrating the semiconductor device according to the second embodiment.

As shown in FIG. 9, in a semiconductor device 121 according to the embodiment, the third electrode 53 need not overlap the second semiconductor layer 12 in the second direction D2.

In the embodiment, information about the shape of the nitride region and the like can be obtained by, for example, electron microscopic observation. Information about the composition and element concentration in the nitride region can be obtained, for example, by EDX (Energy Dispersive X-ray Spectroscopy) or SIMS. Information about the composition in nitride regions may be obtained, for example, by X-ray reciprocal space mapping.

Embodiments may include the following configurations (for example, technical proposals).

### Configuration 1

A semiconductor structure, comprising:
a substrate including silicon crystal;
a first layer including AlN crystal; and
an intermediate region provided between the silicon crystal and the AlN crystal, the intermediate region including Al and nitrogen,
a direction from the silicon crystal to the AlN crystal being along a first direction, and
a third lattice plane spacing in the first direction of a lattice of Al atoms in the intermediate region being longer than a first lattice plane spacing in the first direction of the silicon crystal and longer than a second lattice plane spacing in the first direction of the AlN crystal.

### Configuration 2

The semiconductor structure according to Configuration 1, wherein
a c-plane of the AlN crystal crosses the first direction.

### Configuration 3

The semiconductor structure according to Configuration 1 or 2, wherein
a c-axis of the AlN crystal is along the first direction.

### Configuration 4

The semiconductor structure according to any one of Configurations 1-3, wherein
the second lattice plane spacing is shorter than the first lattice plane spacing.

### Configuration 5

The semiconductor structure according to Configuration 4, wherein
the third lattice plane spacing is 1.1 times or more the first lattice plane spacing.

### Configuration 6

The semiconductor structure according to any one of Configurations 1-3, wherein
the first lattice plane spacing is not less than 0.28 nm and less than 0.32 nm,
the second lattice plane spacing is not less than 0.22 nm and not more than 0.26 nm or less, and
the third lattice plane spacing is not less than 0.32 nm and not more than 0.38 nm.

### Configuration 7

The semiconductor structure according to any one of Configurations 1-6, wherein
a full width at half maximum (FWHM) for the (002) plane of an X-ray diffraction image of the AlN crystal is 1200 arcsec or less.

### Configuration 8

The semiconductor structure according to any one of Configurations 1-7, wherein
a plane of the silicon crystal facing the intermediate region is a (111) plane.

### Configuration 9

The semiconductor structure according to any one of Configurations 1-8, wherein
a thickness of the intermediate region along the first direction is not less than 0.32 nm and not more than 1.0 nm.

### Configuration 10

The semiconductor structure according to any one of Configurations 1-9, wherein
a thickness of the first layer along the first direction is not less than 150 nm and not more than 300 nm.

### Configuration 11

The semiconductor structure according to any one of Configurations 1-10, further comprising:
an AlGaN layer,
the first layer being provided between the substrate and the AlGaN layer.

### Configuration 12

The semiconductor structure according to Configuration 11, further comprising:
a multilayer structure,
the AlGaN layer being provided between the substrate and the multilayer structure.

### Configuration 13

The semiconductor structure according to any one of Configurations 1-10, further comprising:
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first layer being provided between the substrate and the second semiconductor layer, and
the first semiconductor layer being provided between the first layer and the second semiconductor layer.

### Configuration 14

The semiconductor structure according to Configuration 13, further comprising:
a third semiconductor layer including Alₓ₃Ga₁₋ₓ₃N (0≤x3<1, x3<x2) containing carbon, the third semiconductor layer being provided between the first layer and the first semiconductor layer.

### Configuration 15

The semiconductor structure according to Configuration 13 or 14, further comprising:
an AlGaN layer,
the first layer being provided between the substrate and the AlGaN layer.

### Configuration 16

The semiconductor structure according to Configuration 15, further comprising:
a multilayer structure,
the AlGaN layer being provided between the substrate and the multilayer structure.

### Configuration 17

A semiconductor device comprising:
the semiconductor structure according to any one of Configurations 13-15;
a first electrode;
a second electrode; and
a third electrode,
a second direction from the first electrode to the second electrode crossing the first direction,
a position of the third electrode in the second direction being between a position of the first electrode in the second direction and a position of the second electrode in the second direction,
the first semiconductor layer includes a first partial region, a second partial region and a third partial region,
a direction from the first partial region to the first electrode being along the first direction,
a direction from the second partial region to the second electrode being along the first direction,
the third partial region is located between the first partial region and the second partial region in the second direction,
a direction from the third partial region to the third electrode being along the first direction,
the first electrode being electrically connected to the first partial region, and
the second electrode being electrically connected to the second partial region.

### Configuration 18

The semiconductor device according to Configuration 17, wherein
the first semiconductor layer further includes a fourth partial region and a fifth partial region,
the fourth partial region is located between the first partial region and the third partial region in the second direction,
the fifth partial region is located between the third partial region and the second partial region in the second direction,
the second semiconductor layer includes a sixth partial region and a seventh partial region,
a direction from the fourth partial region to the sixth partial region is along the first direction, and
a direction from the fifth partial region to the seventh partial region is along the first direction.

### Configuration 19

The semiconductor device according to Configuration 18, further comprising:
an insulating member,
at least part of the insulating member being located between the third partial region and the third electrode.

### Configuration 20

The semiconductor device according to Configuration 18 or 19, wherein
at least a part of the third electrode is located between the sixth partial region and the seventh partial region in the second direction.

According to the embodiments, it is possible to provide a semiconductor structure and a semiconductor device capable of improving characteristics.

In the specification of the present application, “electrically connected state” includes a state in which a plurality of conductors are physically in contact with each other and current flows between the plurality of conductors. “Electrically connected state” includes a state in which another conductor is inserted between a plurality of conductors and current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor structures and semiconductor devices such as substrates, layers, regions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor structures and semiconductor devices practicable by an appropriate design modification by one skilled in the art based on the semiconductor structures and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor structure, comprising:
a substrate including silicon crystal;
a first layer including AlN crystal; and
an intermediate region provided between the silicon crystal and the AlN crystal, the intermediate region including Al and nitrogen,
a direction from the silicon crystal to the AlN crystal being along a first direction, and
a third lattice plane spacing in the first direction of a lattice of Al atoms in the intermediate region being longer than a first lattice plane spacing in the first direction of the silicon crystal and longer than a second lattice plane spacing in the first direction of the AlN crystal.

2. The semiconductor structure according to claim 1, wherein a c-plane of the AlN crystal crosses the first direction.

3. The semiconductor structure according to claim 1, wherein
a c-axis of the AlN crystal is along the first direction.

4. The semiconductor structure according to claim 1, wherein
the second lattice plane spacing is shorter than the first lattice plane spacing.

5. The semiconductor structure according to claim 4, wherein
the third lattice plane spacing is 1.1 times or more the first lattice plane spacing.

6. The semiconductor structure according to claim 1, wherein
the first lattice plane spacing is not less than 0.28 nm and less than 0.32 nm,
the second lattice plane spacing is not less than 0.22 nm and not more than 0.26 nm or less, and
the third lattice plane spacing is not less than 0.32 nm and not more than 0.38 nm.

7. The semiconductor structure according to claim 1, wherein
a full width at half maximum (FWHM) for the (002) plane of an X-ray diffraction image of the AlN crystal is 1200 arcsec or less.

8. The semiconductor structure according to claim 1, wherein
a plane of the silicon crystal facing the intermediate region is a (111) plane.

9. The semiconductor structure according to claim 1, wherein
a thickness of the intermediate region along the first direction is not less than 0.32 nm and not more than 1.0 nm.

10. The semiconductor structure according to claim 1, wherein
a thickness of the first layer along the first direction is not less than 150 nm and not more than 300 nm.

11. The semiconductor structure according to claim 1, further comprising:
an AlGaN layer,
the first layer being provided between the substrate and the AlGaN layer.

12. The semiconductor structure according to claim 11, further comprising:
a multilayer structure,
the AlGaN layer being provided between the substrate and the multilayer structure.

13. The semiconductor structure according to claim 1, further comprising:
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first layer being provided between the substrate and the second semiconductor layer, and
the first semiconductor layer being provided between the first layer and the second semiconductor layer.

14. The semiconductor structure according to claim 13, further comprising:
a third semiconductor layer including Alₓ₃Ga₁₋ₓ₃N (0≤x3<1, x3<x2) containing carbon,
the third semiconductor layer being provided between the first layer and the first semiconductor layer.

15. The semiconductor structure according to claim 13, further comprising:
an AlGaN layer,
the first layer being provided between the substrate and the AlGaN layer.

16. The semiconductor structure according to claim 15, further comprising:
a multilayer structure,
the AlGaN layer being provided between the substrate and the multilayer structure.

17. A semiconductor device comprising:
the semiconductor structure according to claim 13;
a first electrode;
a second electrode; and
a third electrode,
a second direction from the first electrode to the second electrode crossing the first direction,
a position of the third electrode in the second direction being between a position of the first electrode in the second direction and a position of the second electrode in the second direction,
the first semiconductor layer includes a first partial region, a second partial region and a third partial region,
a direction from the first partial region to the first electrode being along the first direction,
a direction from the second partial region to the second electrode being along the first direction,
the third partial region is located between the first partial region and the second partial region in the second direction,
a direction from the third partial region to the third electrode being along the first direction,
the first electrode being electrically connected to the first partial region, and
the second electrode being electrically connected to the second partial region.

18. The semiconductor device according to claim 17, wherein
the first semiconductor layer further includes a fourth partial region and a fifth partial region,
the fourth partial region is located between the first partial region and the third partial region in the second direction,
the fifth partial region is located between the third partial region and the second partial region in the second direction,
the second semiconductor layer includes a sixth partial region and a seventh partial region,
a direction from the fourth partial region to the sixth partial region is along the first direction, and
a direction from the fifth partial region to the seventh partial region is along the first direction.

19. The semiconductor device according to claim 18, further comprising:
an insulating member,
at least part of the insulating member being located between the third partial region and the third electrode.

20. The semiconductor device according to claim 18, wherein at least a part of the third electrode is located between the sixth partial region and the seventh partial region in the second direction.
